(19) United States
(12) Patent Application Publication
(10) Pub. No.: US 2026/0082913 A1
(43) Pub. Date: Mar. 19, 2026

(54) CERAMIC SUBSTRATE UNIT AND METHOD FOR PRODUCING SAME

(71) Applicant: AMOGREENTECH CO., LTD., Tongjin-eup Gimpo-si, Gyeonggi-do (KR)

(72) Inventor: Jihyung LEE, Tongjin-eup Gimpo-si (KR)

(73) Assignee: AMOGREENTECH CO., LTD., Tongjin-eup Gimpo-si, Gyeonggi-do (KR)

(21) Appl. No.: 19/107,664

(22) PCT Filed: Aug. 30, 2023
(86) PCT No.: PCT/KR2023/012840

§ 371 Date: Feb. 28, 2025

(30) Foreign Application Priority Data
Sep. 1, 2022 (KR) 10-2022-0110488

(51) Int. Cl. H01L 23/473; H01L 21/48; H01L 23/15; H01L 23/498

(52) U.S. Cl. CPC H10W 40/47; H10W 40/037; H10W 70/05; H10W 70/65; H10W 70/692

(57) ABSTRACT

The present disclosure relates to a ceramic substrate unit and a method of manufacturing the same, and is configured such that the ceramic substrate unit includes a ceramic base, an upper metal layer bonded to a top surface of the ceramic base and configured to allow a semiconductor chip to be mounted thereon, a wiring unit including an insulating layer and an electrode layer arranged on the insulating layer, and bonded to a top surface of the upper metal layer, and a heat sink bonded to a bottom surface of the ceramic base, wherein the electrode layer of the wiring unit is connected to the semiconductor chip to form wiring.

### TECHNICAL FIELD

The present disclosure relates to a ceramic substrate unit and a method of manufacturing the ceramic substrate unit, and more particularly to a ceramic substrate unit and a method of manufacturing the ceramic substrate unit, which facilitate the formation of wiring for transferring electrical signals to an upper metal layer.

### BACKGROUND ART

Generally, an electric vehicle requires an inverter that converts a Direct Current (DC) voltage provided by a high voltage battery into a 3-phase Alternating Current (AC) voltage required to drive a motor.

A power module for controlling the high voltage of a driving battery to a state suitable for the motor and supplying the controlled voltage is assembled with the inverter. A power module includes a semiconductor chip for power conversion, and the semiconductor chip generates high-temperature heat due to a high voltage and high current operation. When such heat persists, a problem arises in that the semiconductor chip is degraded and the performance of the power module is deteriorated.

In order to solve this problem, a ceramic substrate to which a thick upper metal layer having high thermal conductivity is applied is used, and due to the large thickness of the upper metal layer, the dimensions of lines/spaces of the ceramic substrate are relatively large. Here, each line indicates a pattern which protrudes upwardly from the plane and extends in a line shape, and each space indicates a gap between lines, wherein the dimensions of the line/space refer to the widths of the corresponding line and the corresponding space in a direction parallel to the plane. For example, when the thickness is 0.3 mm, the line/space may form a circuit having a thickness of 0.5 mm, wherein the time required for an etching process is about 1 hour. On the other hand, when the thickness is 0.8 mm, the line/space need to form a circuit having a thickness of 1.6 mm, and thus a time of about 24 hours or longer is required for an etching process, thus resulting in significant inefficiency.

### SUMMARY OF INVENTION

### Technical Problem

The present disclosure has been made keeping in mind the above problems, and an object of the present disclosure is to provide a ceramic substrate unit and a method of manufacturing the ceramic substrate unit, which do not need to etch an upper metal layer for circuit connection by bonding a separate wiring unit, in which wires for connecting electrical signals are formed, to the upper metal layer, thus realizing cost reduction and reliability improvement, and enabling application to a high-power power module.

### Solution to Problem

To achieve the above object, a ceramic substrate unit according to an embodiment of the present disclosure may include a ceramic base, an upper metal layer bonded to a top surface of the ceramic base and configured to allow a semiconductor chip to be mounted thereon, a wiring unit including an insulating layer and an electrode layer arranged on the insulating layer, and bonded to a top surface of the upper metal layer, and a heat sink bonded to a bottom surface of the ceramic base, wherein the electrode layer of the wiring unit is connected to the semiconductor chip to form wiring.

The insulating layer may be formed of any one of alumina (Al₂O₃), AlN, Si₃N₄, or Zirconia Toughened Alumina (ZTA).

Further, the ceramic substrate unit may further include a bonding layer disposed between the upper metal layer and the wiring unit, wherein the bonding layer is any one of a brazing filler layer, an Ag sintered layer, and a solder layer.

The electrode layer may be formed in a shape corresponding to the insulating layer and then a bottom surface of the electrode layer may be bonded to the insulating layer.

The electrode layer of the wiring unit may be connected to the semiconductor chip through a wire.

The wiring unit may be provided to form a pair, whereby paired wiring units are arranged symmetrically in a diagonal direction.

The electrode layer may be formed along a longitudinal direction of the insulating layer and may be provided to form a pair, whereby paired electrode layers are arranged at intervals in a width direction of the insulating layer.

The electrode layer of the wiring unit may be disposed to be inserted to a certain depth from a top surface of the insulating layer, and the semiconductor chip may be bonded to one end of the electrode layer in a shape of a flip-chip.

The heat sink may include a flat portion having a top surface contacting the ceramic base, and a plurality of protrusions arranged on a bottom surface of the flat portion at intervals, and configured to form a path through which liquid coolant flows.

The plurality of protrusions may be arranged in an external coolant circulation unit, and the liquid coolant circulating through the coolant circulation unit may perform heat exchange with the plurality of protrusions.

The heat sink may be formed of any one of Cu, Al, or a Cu alloy.

A method of manufacturing a ceramic substrate unit according to an embodiment of the present disclosure may include bonding an upper metal layer configured to allow a semiconductor chip to be mounted thereon to a top surface of a ceramic base, bonding a wiring unit including an insulating layer and an electrode layer arranged on the insulating layer to a top surface of the upper metal layer, and bonding a heat sink to a bottom surface of the ceramic base, wherein, in the bonding to the upper metal layer, the electrode layer of the wiring unit is connected to the semiconductor chip through a wire to form wiring.

In the bonding to the top surface of the upper metal layer, the insulating layer may be formed of any one of alumina (Al₂O₃), AlN, Si₃N₄, or Zirconia Toughened Alumina (ZTA).

In the bonding to the top surface of the upper metal layer, the insulating layer of the wiring unit may be bonded to the top surface of the upper metal layer via a bonding layer, and the bonding layer may be any one of a brazing filler layer, an Ag sintered layer, and a solder layer.

### Advantageous Effects of Invention

Because a separate wiring unit functioning as electrical lines is bonded to the top surface of an upper metal layer, the present disclosure does not need to etch the upper metal layer so as to form a power transmission line required for the transfer of electrical signals and power conversion, and may freely design electrode patterns.

Further, because a wiring unit may function as a bridge for connecting signals between a semiconductor chip and a lead frame, the present disclosure does not need to extend the length of wires or to perform an additional etching process on the upper metal layer so as to connect peripheral components such as the semiconductor chip and the lead frame.

Furthermore, since an insulating layer of a wiring unit is formed of any one of alumina (Al₂O₃), AlN, Si₃N₄, or Zirconia Toughened Alumina (ZTA), which is a ceramic material, the present disclosure may obtain excellent thermal stability of the insulating layer even at a high temperature of 700° C. or higher, thereby maintaining the state of stable bonding to an electrode layer.

Furthermore, because the present disclosure is configured such that the insulating layer of a wiring unit and an upper metal layer are bonded to each other in a surface-to-surface manner, the layers may stably maintain the bonded state without being easily separated even at high temperature.

Furthermore, because the electrode of a semiconductor chip may be bonded in a flip-chip shape to one end of an electrode layer in a wiring unit, the present disclosure may skip wire bonding to minimize an inductance value, may convert rated voltage and current while removing electrical risk factors that may occur in wire bonding, and may improve reliability and efficiency when used in high-power devices.

Furthermore, the present disclosure adopts a water-cooled heat dissipation structure in which a plurality of protrusions directly contacts continuously circulating liquid coolant to perform cooling, thus rapidly absorbing and dissipating heat, and maximizing heat dissipation efficiency compared to the conventional air-cooled heat dissipation structure.

Furthermore, even if high-temperature heat is generated from a semiconductor chip or the like, the present disclosure may perform compulsory cooling by continuously circulating liquid coolant to prevent overheating of the ceramic substrate unit and to maintain the semiconductor chip at a constant temperature so as to avoid the degradation of the semiconductor chip.

Furthermore, because liquid coolant flows between a plurality of protrusions, the present disclosure may easily control the flow rate of liquid coolant, cooling efficiency, or the like as the shape, number, and arrangement form of the plurality of protrusions are changed.

### BRIEF DESCRIPTION OF DRAWINGS

FIG. 1 is a top perspective view illustrating a ceramic substrate unit according to an embodiment of the present disclosure.

FIG. 2 is a bottom perspective view illustrating a ceramic substrate unit according to an embodiment of the present disclosure.

FIG. 3 is a conceptual view illustrating a configuration in which a ceramic substrate unit is mounted on a coolant circulation unit and a circulation driving unit is coupled to the coolant circulation unit according to an embodiment of the present disclosure.

FIG. 4 is a plan view illustrating a configuration in which semiconductor chips and lead frames are connected to a ceramic substrate unit according to an embodiment of the present disclosure.

FIG. 5 is a perspective view illustrating a modified example of a ceramic substrate unit according to an embodiment of the present disclosure.

FIG. 6 is a plan view illustrating another modified example of a ceramic substrate unit according to an embodiment of the present disclosure.

FIG. 7 is a side view illustrating the other modified example of a ceramic substrate unit according to an embodiment of the present disclosure.

FIG. 8 is a plan view illustrating a ceramic substrate unit according to another embodiment of the present disclosure.

FIG. 9 is a sectional view taken along line A-A′ of FIG. 8.

FIG. 10 is a flowchart illustrating a method of manufacturing a ceramic substrate unit according to an embodiment of the present disclosure.

### DESCRIPTION OF EMBODIMENTS

### Description

Hereinafter, exemplary embodiments of the present disclosure will be described in detail with reference to the attached drawings.

The embodiments are provided to more completely describe the present disclosure to those skilled in the art, the following embodiments may be modified in various different forms, and the scope of the present disclosure is limited to the following embodiments. Rather, these embodiments are provided to further enrich and complete the present disclosure and to fully convey the spirit of the present disclosure.

Terms used in the present specification are intended to describe specific embodiments and are not intended to limit the present disclosure. In addition, in the present specification, singular forms may include plural forms unless the context clearly indicates otherwise.

In the description of embodiments, when each layer (film), region, pattern, or structure is described as being formed “on” or “under” a substrate, each layer (film), region, pad, or pattern, the terms “on” and “under” encompass “directly” formed structures or “indirectly” formed structures with the interposition of another layer. In addition, the reference for “on” or “under” with respect to each layer is, in principle, based on the drawings.

Drawings are merely intended to help understanding of the spirit of the present disclosure, and should not be construed as limiting the scope of the present disclosure. Furthermore, the relative thickness, length, or size depicted in the drawings may be exaggerated for the convenience and clarity of description.

Hereinafter, embodiments of the present disclosure will be described in detail with reference to the attached drawings.

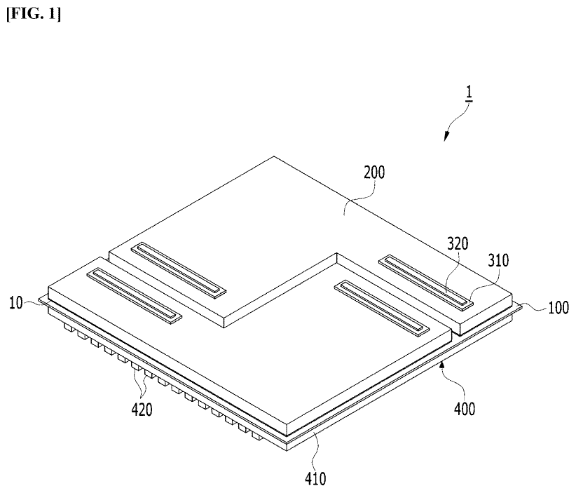

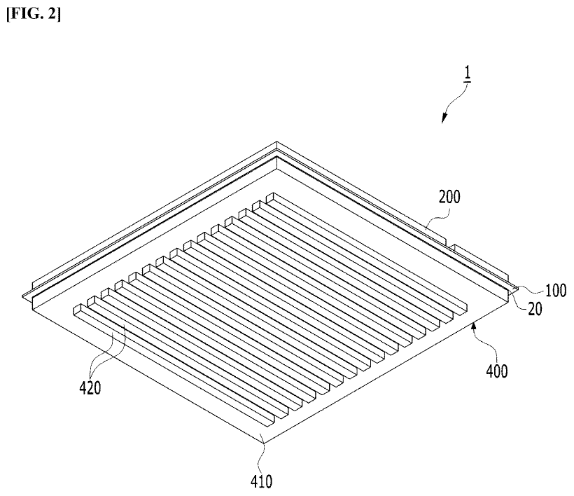

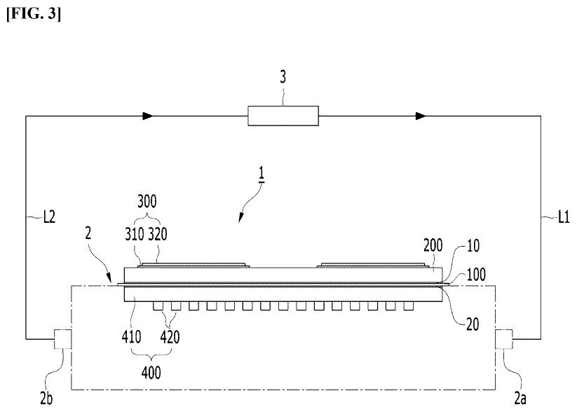

FIG. 1 is a top perspective view illustrating a ceramic substrate unit according to an embodiment of the present disclosure, FIG. 2 is a bottom perspective view illustrating a ceramic substrate unit according to an embodiment of the present disclosure, and FIG. 3 is a conceptual view illustrating a configuration in which a ceramic substrate unit is mounted on a coolant circulation unit and a circulation driving unit is coupled to the coolant circulation unit according to an embodiment of the present disclosure.

As illustrated in FIGS. 1 to 3, a ceramic substrate unit 1 according to an embodiment of the present disclosure may include a ceramic base 100, an upper metal layer 200, a wiring unit 300, and a heat sink 400. In the present embodiment, although description is made based on an Active Metal Brazed (AMB) substrate as an example, a Direct Bonding Copper (DBC) substrate may also be applied. Here, the AMB substrate is the most suitable in terms of durability and heat dissipation efficiency.

The ceramic base 100 may be made of an oxide-based or nitride-based ceramic material. For example, the ceramic base 100 may be, but is not limited to, any one of alumina (Al₂O₃), AlN, SiN, Si₃N₄, Zirconia Toughened Alumina (ZTA).

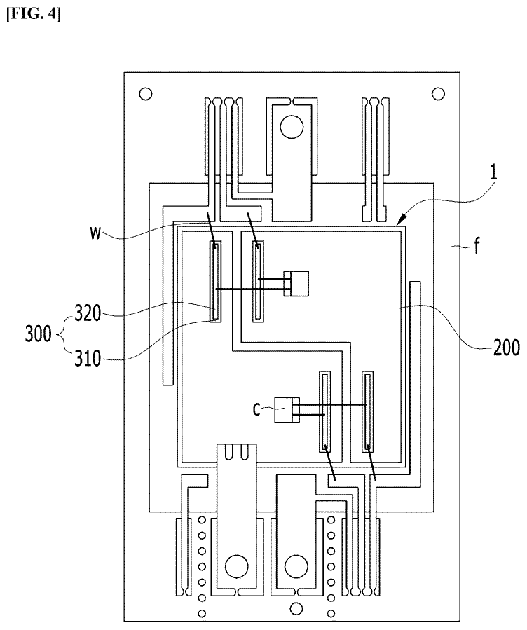

The upper metal layer 200 may be bonded to the top surface of the ceramic base 100, and may be configured such that semiconductor chips c (see FIG. 4) made of SiC, GaN, Si, LED, or VCSEL are mounted thereon. For example, the upper metal layer 200 may be formed of an electrode pattern in a region in which semiconductor chips or peripheral components are to be mounted. Each semiconductor chip c may be mounted on the top surface of the upper metal layer 200 via solder or Ag paste.

The upper metal layer 200 may be made of any one of Cu, Al, or a Cu alloy (CuMo or the like), and may be formed to have a thickness of 0.8 mm or more. In this way, when the upper metal layer 200 is formed at a relatively large thickness of 0.8 mm or more, thermal conductivity and electrical conductivity may become excellent, and thus there is the advantage of being applicable to a power module for high-power power conversion.

The upper metal layer 200 may be bonded to the top surface of the ceramic base 100 via a first bonding layer 10. Here, the first bonding layer 10 may be a brazing filler layer or an Ag sintered layer.

When the first bonding layer 10 is the brazing filler layer, the brazing filler layer may be disposed between the ceramic base 100 and the upper metal layer 200, and may be brazed at a temperature of 450° C. or higher. The brazing filler layer may be formed by a method corresponding to any one of plating, paste application, and foil attachment, and the thickness thereof may range from about 0.005 mm to 1.0 mm. Since the brazing filler layer is formed of a material containing at least one of Ag, Cu, AgCu, and AgCuTi having high thermal conductivity, heat transfer may be facilitated, whereby effective heat dissipation may be realized.

When the first bonding layer 10 is the Ag sintered layer, Ag sinter paste may be disposed between the ceramic base 100 and the upper metal layer 200 and may be sintered at a temperature of about 200° C. in this state, whereby the Ag sintered layer may be formed between the ceramic base 100 and the upper metal layer 200. In this way, Ag sintering bonding using the Ag sintered layer includes the advantage of having high-temperature stability and excellent bonding strength.

Meanwhile, the ceramic base 100 and the upper metal layer 200 may be temporarily bonded through thermochemical bonding, and then brazed. Here, thermochemical bonding may be bonding using thermal fusion, adhesives, pressure-sensitive adhesives or the like. In this way, the ceramic base 100 and the upper metal layer 200 may be hermetically bonded to each other using a bonding method such as brazing bonding or Ag sintering bonding, and thus bonding strength is high and high-temperature reliability is excellent.

The wiring unit 300 may include an insulating layer 310 and an electrode layer 320 arranged on the insulating layer 310. The electrode layer 320 may be formed in a shape corresponding to the insulating layer 310, and the bottom surface thereof may then be bonded to the insulating layer 310. In the present embodiment, although the wiring unit 300 in which the straight line-shaped electrode layer 320 corresponding to the elongated straight insulating layer 310 is bonded onto the insulating layer 310 is illustrated, the shape of the wiring unit 300 is not limited thereto, and the wiring unit may be provided in various shapes in accordance with components such as a lead frame f (see FIG. 4) to which lines are coupled, or a bus bar. For example, the wiring unit 300 may be formed in an ‘L’-shape, ‘U’-shape, or ‘Z’-shape. Because the wiring unit 300 has a shape that extends in one direction and then bends to the left or right, wiring may be formed in more diverse shapes, and greater flexibility may be assigned when signals are connected.

The electrode layer 320 may be formed of conductive metal such as Cu, Ag, Ni—Au, W, Mo, or MoW, and may have a thickness of 0.3 mm or less. Here, the electrode layer 320 may be brazed to the top surface of the insulating layer 310 via a brazing filler, but methods of forming the electrode layer 320 on the insulating layer 310 are not limited thereto. For example, the wiring unit 300 may be formed by forming the electrode layer 320 on the insulating layer 310 and thereafter simultaneously firing the layers. As will be described later with reference to FIG. 4, the electrode layer 320 of the wiring unit 300 may be connected to the corresponding semiconductor chip c mounted on the top surface of the upper metal layer 200 through a wire w, thus forming wiring.

The insulating layer 310 of the wiring unit 300 may be formed of a ceramic material. For example, the insulating layer may be formed of any one of alumina (Al₂O₃), AlN, Si₃N₄, or Zirconia Toughened Alumina (ZTA), which is a ceramic material. The insulating layer 310 may be formed to have a thickness ranging from about 0.015 mm to 0.25 mm.

Because the insulating layer 310 of the ceramic substrate unit 1 according to an embodiment of the present disclosure is formed of a ceramic material, there is the advantage of obtaining excellent thermal stability compared to the use of a material such as polyimide (PI) that is a Flexible Printed Circuit Board (FPCB) material. In case that the insulating layer 310 is formed of polyimide (PI), the insulating layer 310 may be degraded at a high temperature of 200° C. or higher, and then a phenomenon in which the electrode layer 320 is separated from the insulating layer 310 may occur. On the other hand, in case that the insulating layer 310 is formed of any one of alumina (Al₂O₃), AlN, Si₃N₄, or Zirconia Toughened Alumina (ZTA), which is a ceramic material, the thermal stability of the insulating layer 310 may be excellent even at a high temperature of 700° C. or higher, thereby maintaining the state of stable bonding to the electrode layer 320.

FIG. 4 is a plan view illustrating a configuration in which semiconductor chips and lead frames are connected to a ceramic substrate unit according to an embodiment of the present disclosure.

Referring to FIG. 4, the electrode layer 320 may be connected at one end thereof to a semiconductor chip c through a wire w and connected at the other end thereof to a lead part of a lead frame f through a wire w, thereby functioning to transfer electrical signals and functioning as a power transmission line for power conversion. That is, the wiring unit 300 may function as a bridge for connecting signals between the semiconductor chip c and the lead frame f. When the semiconductor chip c and the lead part of the lead frame f are connected only through the wire w without the wiring unit 300, a problem may arise in that, when the distance between the semiconductor chip c and the lead part of the lead frame f is long, the length of the wire w increases to cause loss and the wire is sagging downward, and in that a short circuit may occur during injection of silicon, epoxy or the like.

In order to solve this problem, the ceramic substrate unit 1 according to an embodiment of the present disclosure may be configured such that the wiring unit 300 is bonded to the top surface of the upper metal layer 200. Because the wiring unit 300 may function as a bridge for connecting signals between the semiconductor chip c and the lead frame f, there is no need to extend the length of wires or to perform an additional etching process on the upper metal layer 200 to connect peripheral components such as the semiconductor chip c and the lead frame f.

Since the upper metal layer 200 is thick to such an extent that the thickness thereof is 0.8 mm or more, a problem arises in that it is difficult to form electrode signal line portions for circuit connection or wire bonding regions through etching using equipment, and a long etching time is required. Therefore, because the ceramic substrate unit 1 according to an embodiment of the present disclosure is configured such that a separate wiring unit 300 in which wires are formed is bonded to the top surface of the upper metal layer 200, there are advantages in that the upper metal layer 200 does not need to be etched for circuit connection and the design of electrode patterns may be freely made.

The insulating layer 310 of the wiring unit 300 may be bonded to the top surface of the upper metal layer 200 via a bonding layer (not illustrated). Here, the bonding layer may be any one of a brazing filler layer, an Ag sintered layer, and a solder layer.

When the bonding layer is the brazing filler layer, the brazing filler layer may be disposed between the wiring unit 300 and the upper metal layer 200, and may be brazed at a temperature of 450° C. or higher. The brazing filler layer may be formed by a method corresponding to any one of plating, paste application, and foil attachment, and the thickness thereof may range from about 0.3 μm to 3.0 μm. Since the brazing filler layer is formed of a material containing at least one of Ag, Cu, AgCu, and AgCuTi, which have high thermal conductivity, heat transfer may be facilitated, and then effective heat dissipation may be achieved.

When the bonding layer is the Ag sintered layer, Ag sinter paste may be disposed between the wiring unit 300 and the upper metal layer 200, and may be sintered at a temperature of about 200° C. in this state, whereby the Ag sintered layer may be formed between the wiring unit 300 and the upper metal layer 200. In this way, Ag sintering bonding using the Ag sintered layer includes the advantage of having high-temperature stability and excellent bonding strength.

Furthermore, when the bonding layer is the solder layer, a Sn—Ag-based solder for soldering may be used in the solder layer, and soldering bonding using the Sn—Ag-based solder is stable at high temperatures, thus enabling reliable bonding between the wiring unit 300 and the upper metal layer 200 to be performed. In addition, as the solder, Sn-based, Pb-based, Au-based, In-based, or Bi-based solder may be used.

In this way, the insulating layer 310 of the wiring unit 300 may be bonded to the top surface of the upper metal layer 200 via any one of the brazing filler layer, the AG sintered layer, and the solder layer. In addition, since the insulating layer 310 and the upper metal layer 200 are bonded to each other in a surface-to-surface manner, they may stably maintain a bonded state without being easily separated even at high temperature.

Referring to FIGS. 1 to 3, the heat sink 400 may be bonded to the bottom surface of the ceramic base 100, and may be formed of any one of Cu, Al, or a Cu alloy, which has high thermal conductivity, to perform heat dissipation. The heat sink 400 may include a flat portion 410 and a plurality of protrusions 420. As will be described later, the plurality of protrusions 420 may form a path through which liquid coolant flows. The heat sink 400 may be a heat sink such as microchannel, pin fin, micro jet, slit, or a tube-type heat sink, and the heat sink 400 having the flat portion 410 and the plurality of protrusions 420 will be described in the present embodiment.

The top surface of the flat portion 410 may directly contact the ceramic base 100, and the flat portion 410 may be formed in the shape of a flat panel so that bonding strength is increased by maximizing a bonding area with the ceramic base 100. The plurality of protrusions 420 may be arranged on the bottom surface of the flat portion 410 at intervals, and may form a path through which the liquid coolant flows. In the present embodiment, although a slit-type heat sink 400, in which a plurality of rod-shaped protrusions 420 are horizontally arranged at intervals, is illustrated, the present disclosure is not limited thereto, and the plurality of protrusions 420 may also be provided in various pin shapes, such as a cylindrical shape, a polygonal column shape, a teardrop shape, or a diamond shape. The shape of the protrusions 420 may be implemented through mold processing, etching processing, milling processing, or other processing methods.

As illustrated in FIG. 3, the plurality of protrusions 420 may be arranged in a coolant circulation unit 2. The coolant circulation unit 2 may be provided with an inlet 2a through which liquid coolant flows in, an outlet 2b through which the liquid coolant is discharged, and an internal flow path (not illustrated) extending from the inlet 2a to the outlet 2b. Here, the liquid coolant flowing into the coolant circulation unit 2 through the inlet 2a of the coolant circulation unit 2 may be discharged through the outlet 2b via the internal flow path. Since the shape and size of the internal flow path that is a path through which the liquid coolant is moved between the inlet 2a and the outlet 2b may be designed and modified in various manners, detailed description of the internal flow path itself of the coolant circulation unit 2 will be omitted.

A circulation driving unit 3 may be coupled to the coolant circulation unit 2, and may circulate the liquid coolant using the driving force of a pump (not illustrated). Here, the inlet 2a of the coolant circulation unit 2 may be connected to the circulation driving unit 3 through a first circulation line L1, and the outlet 2b of the coolant circulation unit 2 may be connected to the circulation driving unit 3 through a second circulation line L2. That is, the circulation driving unit 3 may continuously circulate the liquid coolant along a circulation path including the first circulation line L1, the coolant circulation unit 2, and the second circulation line L2. Here, the liquid coolant may be, but is not limited to, deionized water, and may be implemented using liquid nitrogen, alcohol, or other solvents as needed.

The liquid coolant supplied from the circulation driving unit 3 may flow into the inlet 2a of the coolant circulation unit 2 through the first circulation line L1, move along the internal flow path formed in the coolant circulation unit 2, and be discharged through the outlet 2b, after which the liquid coolant may move back to the circulation driving unit 3 through the second circulation line L2. Although not illustrated in detail, the circulation driving unit 3 may include a heat exchanger (not illustrated). The heat exchanger of the circulation driving unit 3 may decrease the temperature of the liquid coolant, the temperature of which has increased while passing through the internal flow path of the coolant circulation unit 2, and the circulation driving unit 3 may supply the liquid coolant, the temperature of which has decreased by the heat exchanger, back to the first circulation line L1 using the driving force of the pump.

In this way, the coolant circulation unit 2 may be provided such that the liquid coolant supplied from the circulation driving unit 3 is continuously circulated. Here, the plurality of protrusions 420 may be arranged in the internal flow path of the coolant circulation unit 2, and may directly contact the liquid coolant continuously circulating along the internal flow path to perform heat exchange. That is, the plurality of protrusions 420 have a water-cooled heat dissipation structure that allows direct cooling by the continuously circulating liquid coolant to be performed.

Even if high-temperature heat is generated from a semiconductor chip c or the like, the plurality of protrusions 420 may be compulsorily cooled by continuously circulating liquid coolant to prevent overheating of the ceramic substrate unit 1 and to maintain the semiconductor chip c at a constant temperature so as to avoid the degradation of the semiconductor chip c. That is, even if high-temperature heat of about 100° C. or higher is generated in the semiconductor chip c, the temperature of the liquid coolant that circulates along the internal flow path of the coolant circulation unit 2 is about 25° C., and thus heat transferred to the plurality of protrusions 420 may be rapidly cooled.

In this way, the ceramic substrate unit 1 according to the embodiment of the present disclosure has a structure in which heat generated from the semiconductor chip C can be directly cooled, thereby enhancing heat dissipation performance while implementing lightweight and small-sized structures.

Further, since the ceramic substrate unit 1 according to the embodiment of the present disclosure employs a water-cooled heat dissipation structure, the flow rate of the liquid coolant may be varied to rapidly absorb and dissipate heat, with the result that the heat dissipation effect may be maximized compared to the conventional air-cooled heat dissipation structure.

The shape, number, and arrangement form of the plurality of protrusions 420 may be variously changed depending on the results of previous simulations during design. Since the liquid coolant flows between the plurality of protrusions 420, the flow rate, cooling efficiency, or the like of the liquid coolant may be easily controlled as the shape, number, and arrangement form of the plurality of protrusions 420 are changed.

The ceramic base 100 and the heat sink 400 may be bonded to each other through a second bonding layer 20. Here, the second bonding layer 20 may be a brazing filler layer or an Ag sintered layer.

When the second bonding layer 20 is the brazing filler layer, the brazing filler layer may be disposed between the flat portion 410 of the heat sink 400 and the ceramic base 100, and may be brazed at a temperature of 450° C. or higher. Here, the brazing filler layer may be formed by a method corresponding to any one of plating, paste application, and foil attachment, and the thickness thereof may range from about 0.005 mm to 1.0 mm. Since the brazing filler layer is formed of a material containing at least one of Ag, Cu, AgCu, and AgCuTi, which have high thermal conductivity, heat transfer may be facilitated, and then effective heat dissipation may be achieved.

When the second bonding layer 20 is the Ag sintered layer, Ag sinter paste may be disposed between the flat portion 410 of the heat sink 400 and the ceramic base 100, and the Ag sintered layer may be formed between the flat portion 410 of the heat sink 400 and the ceramic base 100 as the Ag sinter paste is sintered at a temperature of about 200° C. in this state. In this way, Ag sintering bonding using the Ag sintered layer is advantageous in that high-temperature stability is excellent and bonding strength is superior.

Meanwhile, the ceramic base 100 and the heat sink 400 may be temporarily bonded through thermochemical bonding, and then brazed. Here, thermochemical bonding may be bonding using thermal fusion, adhesives, pressure-sensitive adhesives or the like. As described above, the ceramic base 100 and the heat sink 400 may be hermetically bonded to each other through a bonding method such as brazing or Ag sintering, and may obtain high bonding strength capable of withstanding hydraulic pressure, fluid pressure, or the like.

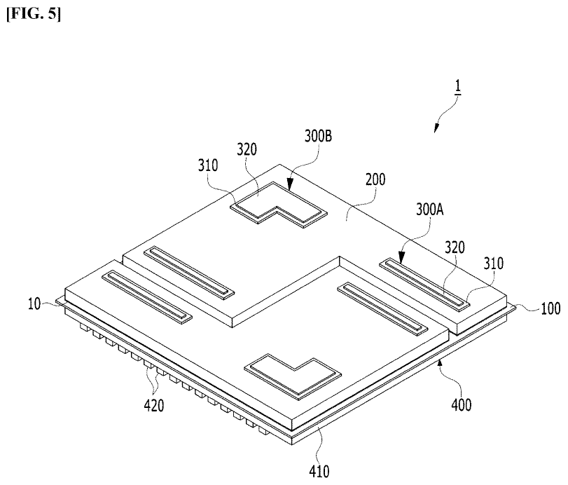

FIG. 5 is a perspective view illustrating a modified example of a ceramic substrate unit according to an embodiment of the present disclosure.

As illustrated in FIG. 5, a ceramic substrate unit 1 may be configured to include a first wiring unit 300A and a second wiring unit 300B. The first wiring unit 300A may have a form in which a straight line-shaped electrode layer 320 corresponding to an elongated straight insulating layer 310 is bonded onto the insulating layer 310. The second wiring unit 300B may have a form in which an ‘L’-shaped electrode layer 320 corresponding to an ‘L’-shaped insulating layer 310 is bonded onto the insulating layer 310. Here, each of the first wiring unit 300A and the second wiring unit 300B may be provided to form a pair, and paired wiring units may be arranged symmetrically in a diagonal direction.

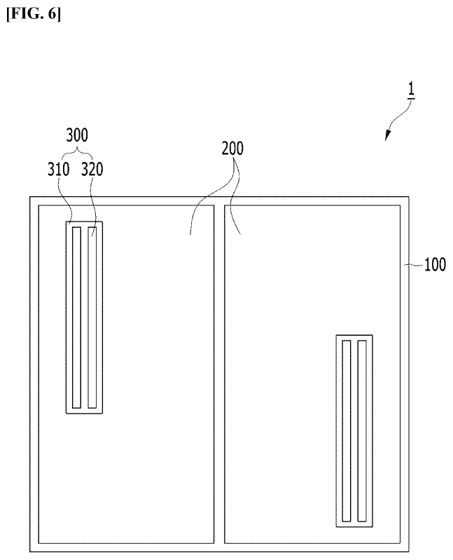

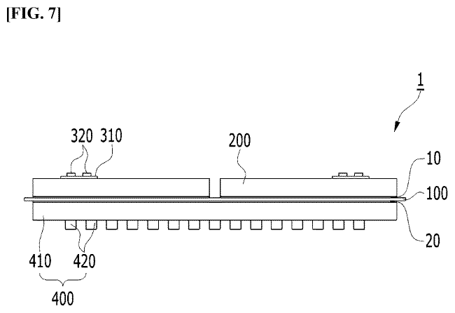

FIG. 6 is a plan view illustrating another modified example of a ceramic substrate unit according to an embodiment of the present disclosure, and FIG. 7 is a side view illustrating another modified example of a ceramic substrate unit according to an embodiment of the present disclosure.

As illustrated in FIGS. 6 and 7, a wiring unit 300 in a ceramic substrate unit 1 may be configured to include an elongated straight insulating layer 310 and electrode layers 320 formed on the top surface of the insulating layer 310 along a longitudinal direction and provided to form a pair to be arranged at intervals in the width direction of the insulating layer 310. In this way, the wiring unit 300 may be provided in various forms to correspond to components such as a lead frame or a bus bar to which lines are connected.

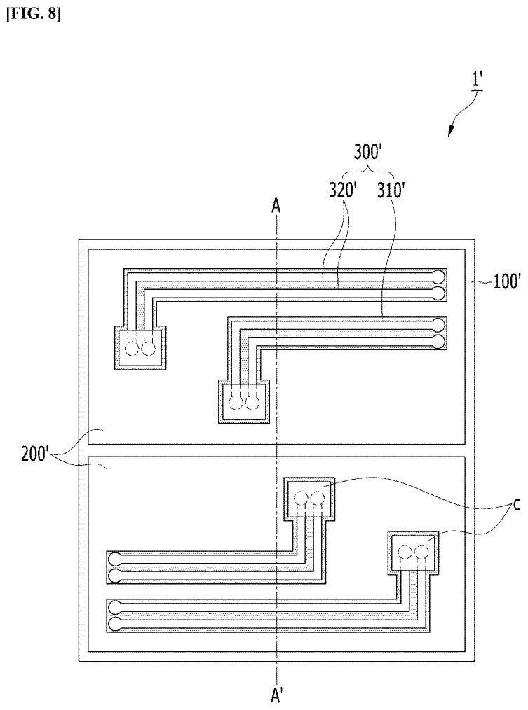

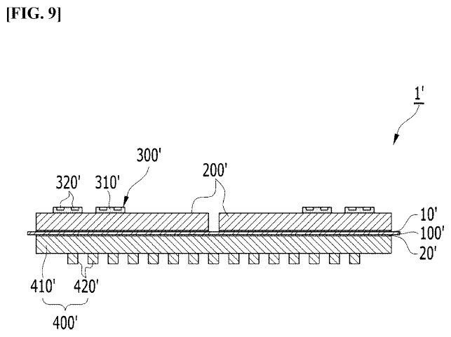

FIG. 8 is a plan view illustrating a ceramic substrate unit according to another embodiment of the present disclosure, and FIG. 9 is a sectional view taken along line A-A′ of FIG. 8.

As illustrated in FIGS. 8 and 9, a wiring unit 300′ of a ceramic substrate unit 1′ according to another embodiment of the present disclosure may be provided such that semiconductor chips c are bonded to the wiring unit 300′ in the shape of flip-chips. Here, electrode layers 320′ of the wiring unit 300′ may be arranged in an upper portion of an insulating layer 310′ and disposed to be inserted to a certain depth from the top surface of the insulating layer 310′. When the electrode of the semiconductor chip c is bonded to one end of each electrode layer 320′ in the form of a flip-chip, wire bonding may be skipped, thereby minimizing an inductance value, and converting rated voltage and current while eliminating electrical risk factors that may occur in wire bonding. In the present embodiment, although an example in which the wiring unit 300′ has an approximately ‘L’-shape is illustrated, the wiring unit 300′ may have a bar shape, as in the case of the embodiment of FIGS. 6 and 7.

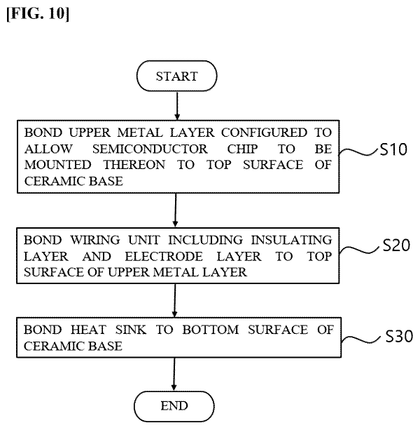

FIG. 10 is a flowchart illustrating a method of manufacturing a ceramic substrate unit according to an embodiment of the present disclosure.

As illustrated in FIG. 10, the method of manufacturing a ceramic substrate according to the embodiment of the present disclosure may include step S10 of bonding an upper metal layer 200 configured such that a semiconductor chip c is mounted therein to the top surface of a ceramic base 100, step S20 of bonding a wiring unit 300 including an insulating layer 310 and an electrode layer 320 arranged on the insulating layer 310 to the top surface of the upper metal layer 200, and step S30 of bonding a heat sink 400 to the bottom surface of the ceramic base 100. Here, individual steps may be performed sequentially, in different orders, or substantially or simultaneously.

In step S10 of bonding the upper metal layer 200 to the top surface of the ceramic base 100, the ceramic base 100 may be made of an oxide-based or nitride-based ceramic material. For example, the ceramic base 100 may be, but is not limited to, any one of alumina (Al₂O₃), AlN, SiN, Si₃N₄, or Zirconia Toughened Alumina (ZTA).

The upper metal layer 200 may be configured such that a semiconductor chip c (see FIG. 4) made of SiC, GaN, Si, LED, VCSEL or the like is mounted thereon. For example, the upper metal layer 200 may be formed of an electrode pattern in a region in which semiconductor chips or peripheral components are to be mounted. The upper metal layer 200 may be made of any one of Cu, Al, or a Cu alloy (CuMo or the like), and may be formed to have a thickness of 0.8 mm or more.

In step S10 of bonding the upper metal layer 200 to the top surface of the ceramic base 100, the upper metal layer 200 may be bonded to the ceramic base 100 via a first bonding layer 10 disposed between the ceramic base 100 and the upper metal layer 200, and the first bonding layer 10 may be a brazing filler layer made of a material containing at least one of Ag, Cu, AgCu and AgCuTi, or an Ag sintered layer made of Ag sinter paste. When the first bonding layer 10 is the brazing filler layer, the brazing filler layer may be formed using a method corresponding to any one of plating, paste application, or foil attachment, and the thickness thereof may range from about 0.005 mm to 1.0 mm. Further, when the first bonding layer 10 is the Ag sintered layer, Ag sinter paste is disposed between the ceramic base 100 and the upper metal layer 200 and is sintered at a temperature of about 200° C. in this state, and thus the Ag sintered layer may be formed.

In step S20 of bonding the wiring unit 300 to the top surface of the upper metal layer 200, the wiring unit 300 may include the insulating layer 310 and the electrode layer 320 arranged on the insulating layer 310. Because the insulating layer 310 of the wiring unit 300 is formed of any one of alumina (Al₂O₃), AlN, Si₃N₄, or Zirconia Toughened Alumina (ZTA), the thermal stability of the insulating layer 310 is excellent even at a high temperature of 700° C. or higher, thereby maintaining the state of stable bonding to the electrode layer 320. Further, the insulating layer 310 may be formed to have a thickness ranging from about 0.015 mm to 0.25 mm.

The electrode layer 320 of the wiring unit 300 may be formed in a shape corresponding to the insulating layer 310, and the bottom surface thereof may then be bonded to the insulating layer 310. The electrode layer 320 may be formed of conductive metal such as Cu, Ag, Ni—Au, W, Mo, or MoW, and may have a thickness of 0.3 mm or less. The electrode layer 320 may be connected to the semiconductor chip c mounted on the top surface of the upper metal layer 200 through a wire w, thus configuring wiring.

In step S20 of bonding the wiring unit 300 to the top surface of the upper metal layer 200, the insulating layer 310 of the wiring unit 300 may be bonded to the top surface of the upper metal layer 200 via a bonding layer, wherein the bonding layer may be any one of a brazing filler layer, an Ag sintered layer, and a solder layer. When the bonding layer is the brazing filler layer, the brazing filler layer may be disposed between the wiring unit 300 and the upper metal layer 200, and may be brazed at a temperature of 450° C. or higher. The brazing filler layer may be formed by a method corresponding to any one of plating, paste application, and foil attachment, and the thickness thereof may range from about 0.3 μm to 3.0 μm. Since the brazing filler layer is formed of a material containing at least one of Ag, Cu, AgCu, and AgCuTi, which have high thermal conductivity, heat transfer may be facilitated, and then effective heat dissipation may be achieved.

When the bonding layer is the Ag sintered layer, Ag sinter paste may be disposed between the wiring unit 300 and the upper metal layer 200, and may be sintered at a temperature of about 200° C. in this state, whereby the Ag sintered layer may be formed between the wiring unit 300 and the upper metal layer 200. In this way, Ag sintering bonding using the Ag sintered layer is advantageous in that high-temperature stability is excellent and bonding strength is superior. Furthermore, when the bonding layer is the solder layer, a Sn—Ag-based solder for soldering may be used in the solder layer, and soldering bonding using the Sn—Ag-based solder is stable at high temperatures, thus enabling reliable bonding between the wiring unit 300 and the upper metal layer 200 to be performed. In addition, Sn-based, Pb-based, Au-based, In-based, or Bi-based solder may be used as the solder.

In step S30 of bonding the heat sink 400 to the bottom surface of the ceramic base 100, the heat sink 400 may be made of a material such as Cu, Al, or a Cu alloy, which has high thermal conductivity, so as to perform heat dissipation, and may be provided with a flat portion 410 and a plurality of protrusions 420. The flat portion 410 may be a portion in which the top surface thereof directly contacts the ceramic base 100, and may be provided in the shape of a flat panel to maximize a bonding area. The plurality of protrusions 420 may be arranged on the bottom surface of the flat portion 410 at intervals. The plurality of protrusions 420 may be arranged in an external coolant circulation unit 2 (see FIG. 3) and provided to directly contact liquid coolant that circulates through the coolant circulation unit 2.

In step S30 of bonding the heat sink 400 to the bottom surface of the ceramic base 100, the heat sink 400 may be bonded to the ceramic base 100 via a second bonding layer 20 disposed between the flat portion 410 of the heat sink 400 and the ceramic base 100, and the second bonding layer 20 may be a brazing filler layer made of a material containing at least one of Ag, Cu, AgCu and AgCuTi, or an Ag sintered layer made of Ag sinter paste. When the second bonding layer 20 is the brazing filler layer, the brazing filler layer may be formed using a method corresponding to any one of plating, paste application, or foil attachment, and the thickness thereof may range from about 0.005 mm to 1.0 mm. Further, when the second bonding layer 20 is the Ag sintered layer, Ag sinter paste is disposed between the flat portion 410 of the heat sink 400 and the ceramic base 100 and is sintered at a temperature of about 200° C. in this state, and thus the Ag sintered layer may be formed.

The above-described ceramic substrate unit according to the present disclosure may be applied to a power module to ensure both multiple and large-scale connections of semiconductor chips and heat dissipation effect, and may also contribute to small-size implementation to further enhance the performance of the power module.

The above-described ceramic substrate unit according to the present disclosure may be applied to various module components used for high power, in addition to the power module.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the scope of the claims and equivalents thereof should be construed as being included in the scope of the present disclosure.

1. A ceramic substrate unit, comprising:
a ceramic base;
an upper metal layer bonded to a top surface of the ceramic base and configured to allow a semiconductor chip to be mounted thereon;
a wiring unit including an insulating layer and an electrode layer arranged on the insulating layer, and bonded to a top surface of the upper metal layer; and
a heat sink bonded to a bottom surface of the ceramic base,
wherein the electrode layer of the wiring unit is connected to the semiconductor chip to form wiring.

2. The ceramic substrate unit of claim 1, wherein the insulating layer is formed of any one of alumina (Al₂O₃), AlN, Si₃N₄, or Zirconia Toughened Alumina (ZTA).

3. The ceramic substrate unit of claim 1, further comprising:
a bonding layer disposed between the upper metal layer and the wiring unit,
wherein the bonding layer is any one of a brazing filler layer, an Ag sintered layer, and a solder layer.

4. The ceramic substrate unit of claim 1, wherein the electrode layer is formed in a shape corresponding to the insulating layer and then a bottom surface of the electrode layer is bonded to the insulating layer.

5. The ceramic substrate unit of claim 1, wherein the electrode layer of the wiring unit is connected to the semiconductor chip through a wire.

6. The ceramic substrate unit of claim 1, wherein the wiring unit is provided to form a pair, whereby paired wiring units are arranged symmetrically in a diagonal direction.

7. The ceramic substrate unit of claim 1, wherein the electrode layer is formed along a longitudinal direction of the insulating layer and is provided to form a pair, whereby paired electrode layers are arranged at intervals in a width direction of the insulating layer.

8. The ceramic substrate unit of claim 1, wherein the electrode layer of the wiring unit is disposed to be inserted to a certain depth from a top surface of the insulating layer, and the semiconductor chip is bonded to one end of the electrode layer in a shape of a flip-chip.

9. The ceramic substrate unit of claim 1, wherein the heat sink comprises:
a flat portion having a top surface contacting the ceramic base; and
a plurality of protrusions arranged on a bottom surface of the flat portion at intervals, and configured to form a path through which liquid coolant flows.

10. The ceramic substrate unit of claim 9, wherein:
the plurality of protrusions are arranged in an external coolant circulation unit, and
the liquid coolant circulating through the coolant circulation unit performs heat exchange with the plurality of protrusions.

11. The ceramic substrate unit of claim 1, wherein the heat sink is formed of any one of Cu, Al, or a Cu alloy.

12. A method of manufacturing a ceramic substrate unit, comprising:
bonding an upper metal layer configured to allow a semiconductor chip to be mounted thereon to a top surface of a ceramic base;
bonding a wiring unit including an insulating layer and an electrode layer arranged on the insulating layer to a top surface of the upper metal layer; and
bonding a heat sink to a bottom surface of the ceramic base,
wherein, in the bonding to the upper metal layer,
the electrode layer of the wiring unit is connected to the semiconductor chip through a wire to form wiring.

13. The method of claim 12, wherein:
in the bonding to the top surface of the upper metal layer,
the insulating layer is formed of any one of alumina (Al₂O₃), AlN, Si₃N₄, or Zirconia Toughened Alumina (ZTA).

14. The method of claim 12, wherein:
in the bonding to the top surface of the upper metal layer,
the insulating layer of the wiring unit is bonded to the top surface of the upper metal layer via a bonding layer, and
the bonding layer is any one of a brazing filler layer, an Ag sintered layer, and a solder layer.
